(19) United States
(12) Patent Application Publication
(10) Pub. No.: US 2014/0167093 A1
(43) Pub. Date: Jun. 19, 2014

(54) LIGHT EMITTING DIODE HAVING A PLURALITY OF HEAT CONDUCTIVE COLUMNS

(71) Applicant: HON HAI PRECISION INDUSTRY CO., LTD., New Taipei (TW)

(72) Inventor: CHIH-CHEN LAI, New Taipei (TW)

(73) Assignee: HON HAI PRECISION INDUSTRY CO., LTD., New Taipei (TW)

(21) Appl. No.: 13/848,696

(22) Filed: Mar. 21, 2013

(30) Foreign Application Priority Data
Dec. 13, 2012 (TW) 101147113

(51) Int. Cl. H01L 33/64

(52) U.S. Cl. CPC H01L 33/642
USPC 257/99

(57) ABSTRACT

An LED (light emitting diode) includes a substrate, a first electrode and a second electrode located on the substrate, and an LED chip electrically connected to the first electrode and the second electrode. The substrate includes a ceramic plate and a plurality of metallic heat conductive columns inserted in an interior of the plate. The plurality of heat conductive columns is spaced from each other and all located rightly underneath the LED chip. The LED chip is thermally connected to the plurality of heat conductive columns.

### BACKGROUND

1. Technical Field

The present disclosure relates to an LED (light emitting diode), and more particularly to an LED having a high heat dissipating efficiency.

2. Description of Related Art

LEDs have been widely promoted as light sources of electronic devices owing to many advantages, such as high luminosity, low operational voltage and low power consumption. However, with the increasing of the output of the LED, the power the LED consumed and lost is greater, and the heat the LED generated is larger. Traditionally, the LED includes a substrate supporting the LED chip. However, the substrate is made of ceramic material, wherein the heat conductivity of the ceramic material is not good enough; the heat generated by the LED chip is dissipated away insufficiently.

Therefore, an LED capable of overcoming the above described shortcomings is desired.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows a cross-sectional view of an LED in accordance with an embodiment of the present disclosure.

FIG. 2 shows a top view of a substrate of the LED illustrated in FIG. 1 of the present disclosure.

### DETAILED DESCRIPTION

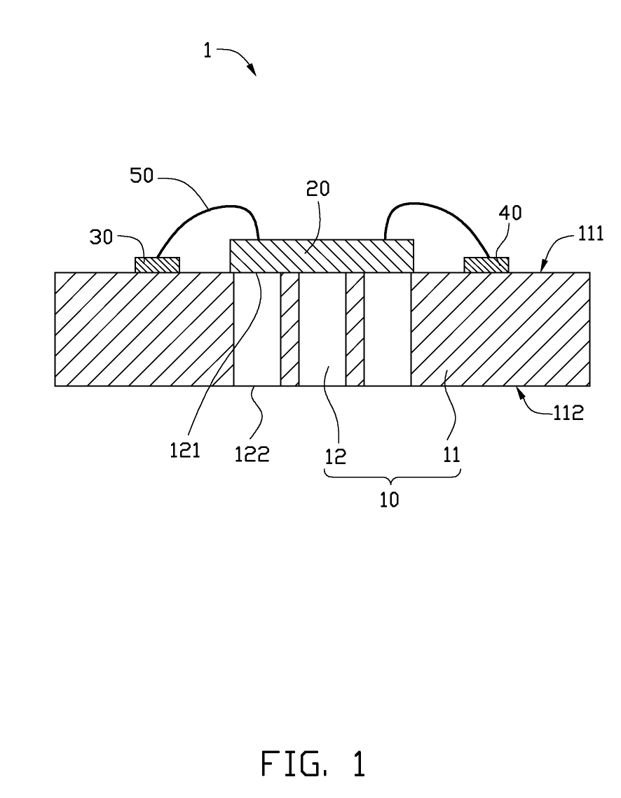

Referring to FIG. 1, an LED 1 in accordance with an exemplary embodiment of the present disclosure includes a substrate 10, a first electrode 30 and a second electrode 40 located on the substrate 10, and an LED chip 20 electrically connected to the first electrode 30 and the second electrode 40. The LED chip 20 is located on the substrate 10.

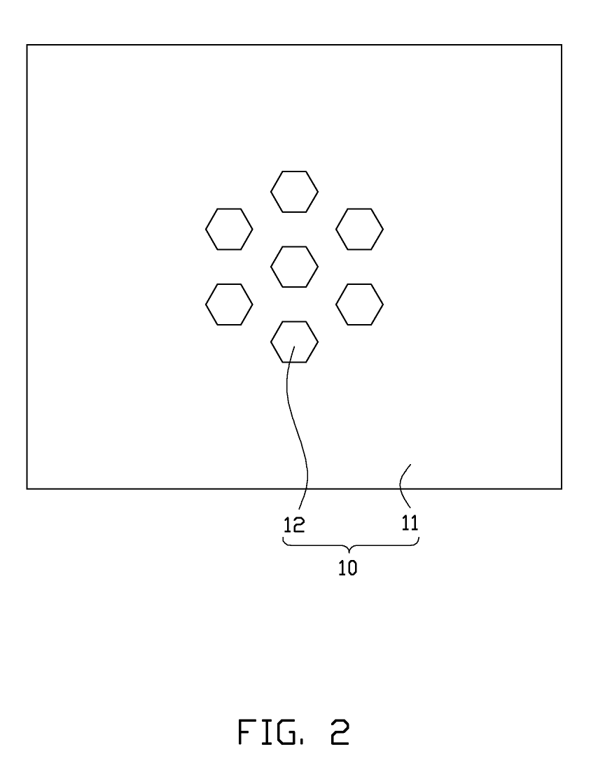

Referring to FIG. 2, the substrate 10 includes a plate 11 and a plurality of heat conductive columns 12 inserted in an interior of the plate 11. The plurality of heat conductive columns 12 are spaced from each other. The plate 11 includes an upper surface 111 and a lower surface 112 opposite to the upper surface 111. In this embodiment, the plate 11 is made of electrically insulating material, such as ceramic, resin or polymer material. The plurality of heat conductive columns 12 each have a top surface 121 and a bottom surface 122 opposite to the top surface 121. The top surface 121 and the bottom surface 122 of each heat conductive column 12 are coplanar with the upper surface 111 and the lower surface 112 of the plate 11, respectively. In this embodiment, the plurality of heat conductive columns 12 is equidistantly arranged in the plate 11. Concretely, the plurality of heat conductive columns 12 is arranged in the plate 11 in a honeycomb-shaped manner, and each heat conductive column 12 has a shape of a hexagonal prism. The heat conductive column 12 is made of metal with high heat conductivity, such as aluminum, copper or silver. Alternatively, the heat conductive columns 12 each can also be cuboid or cylinder shaped.

The LED chip 20 is located on the upper surface 111 of the substrate 10, and located rightly on the top of the plurality of heat conductive columns 12. The LED chip 20 is in contact with and thermally connected to the plurality of spaced heat conductive columns 12. The first electrode 30 and the second electrode 40 are both located on the upper surface 111 of the substrate 10, and located on two lateral sides of the plurality of spaced heat conductive columns 12. The LED chip 20 is electrically connected to the first electrode 30 and the second electrode 40 respectively by two wires 50. In this embodiment, the LED chip 20 is directly attached to the top surfaces 121 of the plurality of spaced heat conductive columns 12 and the upper surface 111 of the plate 11 around the heat conductive columns 12.

During operation of the LED 1, the LED chip 20 generates a large amounts of heat. Due to the plurality of spaced heat conductive columns 12 located in the interior of the plate 11, the heat generated by the LED chip 20 can be passed to the plurality of spaced heat conductive columns 12 quickly. Therefore, the heat is dissipated away sufficiently, and the service life of the LED 1 is improved.

Additionally, due to each heat conductive column 12 having a small volume, an expansion force generated by the heat conductive column 12 when the heat conductive column 12 is expanded by absorbing heat from the LED chip 20 in operation is relatively small. Accordingly, the deformation of expansion of the heat conductive column 12 can be effectively restrained by the plate 11, so the heat conductive columns 12 will not be unduly deformed when absorbing the heat from the LED chip 12, whereby the LED chip 20 will not be damaged due to the expansion of the heat conductive columns 12, which may happen when the heat conductive columns 12 are integrally formed as a single block. Additionally, the heat generated by the LED 1 can be dissipated away effectively by the plurality of heat conductive columns 12, so that the heat dissipating efficiency can be improved by the way of inserting the heat conductive columns 12 in the plate 11, and the service life of the LED 1 is accordingly improved.

It is understood that, when a distance between two adjacent heat conductive columns 12 is increased, a quantity of the heat conductive columns 12 located rightly below the LED chip 20 is decreased, so that the extent of expansion of the heat conductive columns 12 is decreased, and the probability of damage to the LED chip 20 due to the expansion of the conductive columns 12 is decreased. To the contrary, when a distance between the two adjacent heat conductive columns 12 is decreased, a quantity of the heat conductive columns 12 located right below the LED chip 20 is increased, so a total volume of the heat conductive columns 12 is increased, and the heat dissipating efficiency of the LED 1 can be improved. A trade-off between the heat dissipating efficiency and the extent of expansion of the heat conductive columns 12 can be easily attained by a persons skilled in the art after some routine experiments.

Particular embodiments are shown and described by way of illustration only. The principles and the features of the present disclosure may be employed in various and numerous embodiments thereof without departing from the scope of the disclosure as claimed. The above-described embodiments illustrate the scope of the disclosure but do not restrict the scope of the disclosure.

What is claimed is:

1. An LED (light emitting diode), comprising:
a substrate;
a first electrode and a second electrode located on the substrate; and
an LED chip electrically connected to the first electrode and the second electrode;
wherein the substrate comprises a plate and a plurality of heat conductive columns inserted in an interior of the plate, the plurality of heat conductive columns is spaced from each other and all located rightly underneath the LED chip, and the LED chip is thermally connected to the plurality of heat conductive columns, each heat conductive column having a heat conductivity higher that that of the plate.

2. The LED of claim 1, wherein the plate comprises an upper surface and a lower surface opposite to the upper surface, the LED chip and the first and second electrodes are all located on the upper surface of the plate, each of the heat conductive columns comprises a top surface and a bottom surface opposite to the top surface, and the top surface and the bottom surface of each heat conductive column are coplanar with the upper surface and the lower surface of the plate, respectively.

3. The LED of claim 1, wherein the plate is made of electrically insulating material.

4. The LED of claim 1, wherein the heat conductive column is made of electrically conductive material.

5. The LED of claim 1, wherein the plurality of heat conductive columns is equidistantly arranged in the plate.

6. The LED of claim 5, wherein the plurality of heat conductive columns is arranged in a honeycomb-shaped manner in the plate.

7. The LED of claim 1, wherein each heat conductive column is prism, cuboid or cylinder shaped.

8. An LED (light emitting diode), comprising:
a substrate;
a first electrode and a second electrode located on the substrate; and
an LED chip electrically connected to the first electrode and the second electrode;
wherein the substrate comprises a plate and a plurality of heat conductive columns inserted in an interior of the plate, the plurality of heat conductive columns are spaced from each other, and the LED chip is in contact with and thermally connected to the plurality of heat conductive columns.

9. The LED of claim 8, wherein the plate comprises an upper surface and a lower surface opposite to the upper surface, the LED chip and the first and second electrodes are all located on the upper surface of the plate, each of the heat conductive columns comprises a top surface and a bottom surface opposite to the top surface, and the top surface and the bottom surface of each heat conductive column are coplanar with the upper surface and the lower surface of the plate, respectively.

10. The LED of claim 8, wherein the plate is made of electrically insulating material.

11. The LED of claim 8, wherein the heat conductive column is made of electrically conductive material.

12. The LED of claim 8, wherein the plurality of heat conductive columns is equidistantly arranged in the plate.

13. The LED of claim 12, wherein the plurality of heat conductive columns is arranged in the plate in a honeycomb-shaped manner.

14. The LED of claim 8, wherein each heat conductive column is prism, cuboid or cylinder shaped.

15. The LED of claim 8, wherein the plate is made of ceramic and the heat conductive columns each are made of metal.

16. An LED comprising:
a substrate comprising a ceramic plate and a plurality of metallic heat conductive columns spaced from each other and inserted in the ceramic plate; and
an LED chip mounted on and in contact with top surfaces of the metallic conductive columns and a top surface of the ceramic plate around the metallic conductive columns.

17. The LED of claim 16, wherein the metallic heat conductive columns are arranged in a honeycomb-shaped manner in the ceramic plate.

18. The LED of claim 17, wherein each metallic heat conductive column has a shape of a hexagonal prism.
